(19) United States
(12) Patent Application Publication
(10) Pub. No.: US 2025/0046627 A1
(43) Pub. Date: Feb. 6, 2025

(54) SUBSTRATE PROCESSING APPARATUS AND SUBSTRATE PROCESSING METHOD

(71) Applicant: Tokyo Electron Limited, Tokyo (JP)

(72) Inventor: Hiroki SAKURAI, KUMAMOTO (JP)

(73) Assignee: Tokyo Electron Limited, Tokyo (JP)

(21) Appl. No.: 18/782,194

(22) Filed: Jul. 24, 2024

(30) Foreign Application Priority Data
Jul. 31, 2023 (JP) 2023-124169

(51) Int. Cl. H01L 21/67

(52) U.S. Cl. CPC H01L 21/67051

(57) ABSTRACT

A substrate processing apparatus includes a rotational holding part that holds a substrate, a cleaning nozzle that discharges a mixed fluid of a cleaning liquid and a gas onto the substrate, a liquid supply nozzle that discharges a liquid onto the substrate, and a controller, wherein the controller executes, at least, discharging the liquid from the liquid supply nozzle to a central part of the substrate, discharging the cleaning liquid from the cleaning nozzle to a central part of the substrate, discharging the gas at a first flow rate from the cleaning nozzle onto the substrate to discharge the mixed fluid to a central part of the substrate, and moving the cleaning nozzle and the liquid supply nozzle from a central part to a peripheral part of the substrate while changing a flow rate of the gas to a second flow rate that is greater than the first flow rate.

### CROSS-REFERENCE TO RELATED APPLICATION(S)

This application is based on, and claims the benefit of priority to, Japanese Patent Application No. 2023-124169 filed on Jul. 31, 2023, the entire contents of which are incorporates by reference.

### FIELD

A disclosed embodiment(s) relate(s) to a substrate processing apparatus and a substrate processing method.

### BACKGROUND

A technique has been known that discharges a mixed fluid of a cleaning liquid and a gas to a substrate such as a semiconductor wafer, for example, so as to remove a removal target such as a resist film from the substrate and clean the substrate in a manufacturing process for a semiconductor device (Japanese Patent Application Publication No. 2003-203892).

### SUMMARY

A substrate processing apparatus according to an embodiment includes a rotational holding part that holds a substrate rotatably, a cleaning nozzle that is provided movably at an upper side of the substrate that is heled by the rotational holding part and rotates, from a central part to a peripheral part of the substrate, and discharges a mixed fluid of a cleaning liquid and a gas onto the substrate, a liquid supply nozzle that is provided movably at an upper side of the substrate, integrally with the cleaning nozzle, and discharges a liquid onto the substrate, and a controller that controls at least the rotational holding part, the cleaning nozzle, and the liquid supply nozzle, wherein the cleaning nozzle is capable of discharging each of the cleaning liquid and the gas independently, and the controller is configured to execute, at least, discharging the liquid from the liquid supply nozzle to a central part of the substrate to form a liquid film of the liquid on the substrate, discharging the cleaning liquid from the cleaning nozzle to a central part of the substrate where a liquid film of the liquid has been formed, discharging the gas at a first flow rate from the cleaning nozzle onto the substrate to discharge the mixed fluid to a central part of the substrate, and moving the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

### BRIEF DESCRIPTION OF DRAWINGS

FIG. 1 is a schematic diagram that illustrates an example of a specific configuration of a substrate processing apparatus according to an embodiment.

FIG. 2 is a diagram for explaining a cleaning process according to an embodiment.

FIG. 3 is a diagram for explaining a cleaning process according to an embodiment.

FIG. 4 is a diagram for explaining a cleaning process according to an embodiment.

FIG. 5 is a diagram for explaining a cleaning process according to an embodiment.

FIG. 6 is a diagram for explaining a cleaning process according to an embodiment.

FIG. 7 is a diagram for explaining a cleaning process according to an embodiment.

FIG. 8 is a diagram for explaining a cleaning process according to an embodiment.

FIG. 9 is a diagram for explaining a cleaning process according to an embodiment.

FIG. 10 is a diagram for explaining a cleaning process according to an embodiment.

FIG. 11 is a diagram for explaining a cleaning process according to an embodiment.

FIG. 12 is a diagram that illustrates an example of a transition of a flow rate of a processing gas that is discharged from a cleaning nozzle in a cleaning process in a reference example.

FIG. 13 is a diagram that illustrates an example of a transition of a flow rate of a processing gas that is discharged from a cleaning nozzle in a cleaning process according to an embodiment.

FIG. 14 is a diagram for explaining a rinsing process according to an embodiment.

FIG. 15 is a diagram for explaining a rinsing process according to an embodiment.

FIG. 16 is a diagram for explaining a rinsing process according to an embodiment.

FIG. 17 is a diagram for explaining a rinsing process according to an embodiment.

FIG. 18 is a diagram for explaining a rinsing process according to an embodiment.

FIG. 19 is a flowchart that illustrates an example of a procedure of substrate processing that is executed by a substrate processing apparatus according to an embodiment.

FIG. 20 is a flowchart that illustrates an example of a procedure of a cleaning process that is executed by a substrate processing apparatus according to an embodiment.

FIG. 21 is a flowchart that illustrates an example of a procedure of a rinsing process that is executed by a substrate processing apparatus according to an embodiment.

FIG. 22 is a flowchart that illustrates another example of a procedure of a cleaning process that is executed by a substrate processing apparatus according to an embodiment.

### DESCRIPTION OF EMBODIMENTS

Hereinafter, an embodiment(s) of a substrate processing apparatus and a substrate processing method as disclosed in the present application will be explained in detail with reference to the accompanying drawing(s). Additionally, the present disclosure is not limited by an embodiment(s) as illustrated below. Furthermore, the drawing(s) is/are schematic where it should be noted that a relationship between dimensions of respective elements, a ratio of respective elements, etc., may be different from a reality. Moreover, parts with dimension relationships or ratios that are different from one another may be included among mutual drawings.

A technique has been known that discharges a mixed fluid of a cleaning liquid and a gas to a substrate such as a semiconductor wafer, for example, so as to remove a removal target such as a resist film from the substrate and clean the substrate in a manufacturing process for a semiconductor device.

In such a cleaning process, for example, a liquid is supplied from a liquid supply nozzle that is arranged so as to be adjacent to a two-fluid nozzle that discharges a mixed fluid, so that a cleaning process is executed with such a mixed fluid while a liquid film is formed on a front surface of a substrate.

However, in a conventional technique as described above, a splash of a large amount of a liquid may occur on a substrate when a mixed fluid is discharged from a two-fluid nozzle to a liquid film on such a substrate. Then, each nozzle may be contaminated by such a splash of a large amount of a liquid so as to generate a large number of particles on a substrate.

Hence, realization of a technique is expected that is capable of solving a problem(s) as described above and reducing or preventing occurring of a liquid splash on a substrate in a cleaning process with a mixed fluid.

### Configuration of Substrate Processing Apparatus

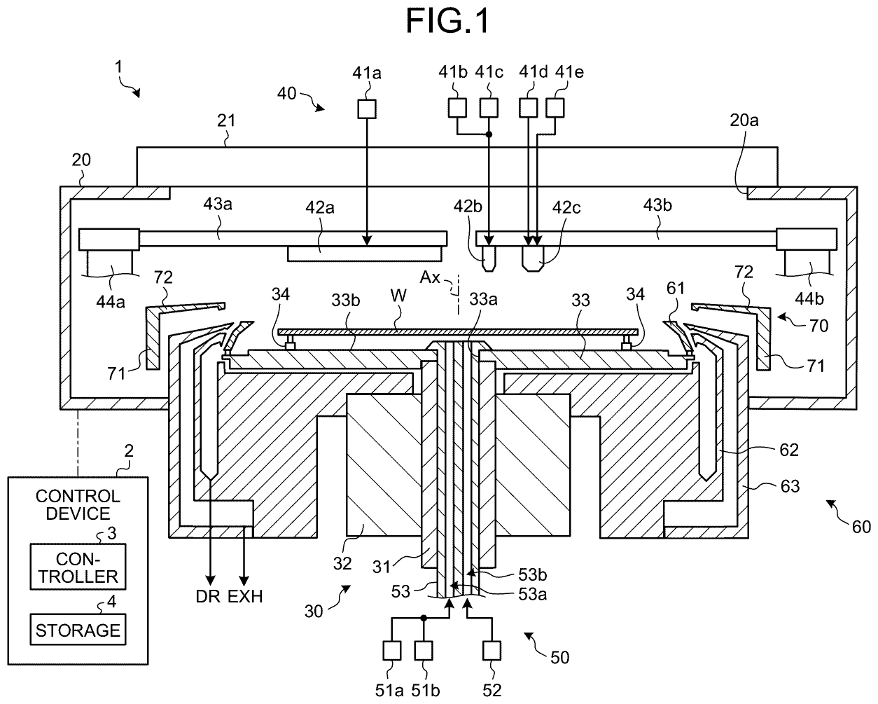

First, a configuration of a substrate processing apparatus 1 according to an embodiment will be explained with reference to FIG. 1. FIG. 1 is a schematic diagram that illustrates an example of a specific configuration of the substrate processing apparatus 1 and is a schematic cross-sectional view in a case where the substrate processing apparatus 1 is viewed from a lateral side thereof.

As illustrated in FIG. 1, the substrate processing apparatus 1 includes a processing chamber 20, a rotational holding part 30, an upper side supply part 40, a lower side supply part 50, a cup body 60, and a mist guard 70.

Furthermore, the substrate processing apparatus 1 includes a control device 2. The control device 2 is, for example, a computer and includes a controller 3 and a storage 4. The storage 4 stores a program that controls various types of processes that are executed in the substrate processing apparatus 1. The controller 3 reads and executes a program that is stored in the storage 4 so as to control an operation of the substrate processing apparatus 1.

Additionally, such a program may be recorded in a computer-readable storage medium and installed in the storage 4 of the control device 2 from such a storage medium. For a computer-readable storage medium, for example, a hard disk (HD), a flexible click (FD), a compact disk (CD), a magnetooptical disk (MO), a memory card, etc., are provided.

The processing chamber 20 is configured in such a manner that processing of a wafer with a processing fluid is executed in an inside thereof. The processing chamber 20 houses the rotational holding part 30, the upper side supply part 40, the lower side supply part 50, the cup body 60, and the mist guard 70.

As illustrated in FIG. 1, a Fan Filter Unit (FFU) 21 is attached thereto so as to cover an opening 20a that is formed on a top wall of the processing chamber 20. The FFU 21 forms a downflow in the processing chamber 20.

A non-illustrated carrying-in/out port is formed on the substrate processing apparatus 1. A wafer W is transferred to an inside of the processing chamber 20 through a carrying-in/out port, and further, is carried out of the processing chamber 20 to an outside thereof through such a carrying-in/out port, by a non-illustrated substrate transfer device. Furthermore, a non-illustrated shutter is provided for a carrying-in/out port at a position that plugs such a carrying-in/out port and is configured to be capable of opening and closing such a carrying-in/out port.

As illustrated in FIG. 1, the rotational holding part 30 has a rotational shaft 31, a driving unit 32, a substrate holding part 33, and a plurality of support pins 34. The rotational shaft 31 is a hollow tubular member that extends along a vertical direction. The rotational shaft 31 is configured to be rotatable around a central axis Ax.

The driving unit 32 is connected to the rotational shaft 31. The driving unit 32 is operated based on a signal from the controller 3 so as to rotate the rotational shaft 31. The driving unit 32 may be, for example, a power source such as an electrical motor.

The substrate holding part 33 holds a wafer W horizontally. For example, the substrate holding part 33 is a flat plate that has a ring shape and extends horizontally. That is, a through-hole 33a is formed on a central part of the substrate holding part 33. An inner peripheral part of the substrate holding part 33 is connected to a tip part of the rotational shaft 31. Hence, the substrate holding part 33 is rotated with rotation of the rotational shaft 31 around a central axis Ax of the rotational shaft 31.

The plurality of support pins 34 are provided so as to protrude upwardly from an upper surface 33b of the substrate holding part 33. The plurality of support pins 34 support a wafer W substantially horizontally in such a manner that tips thereof contact a back surface of such a wafer W. For example, a support pin 34 may have a cylindrical shape or may have a frustum shape.

The plurality of support pins 34 may be arranged at a substantially regular interval(s) near an outer peripheral part of the substrate holding part 33 so as to have a circular shape as a whole when viewed from an upper side thereof. For example, in a case where the number of the plurality of support pins 34 is twelve, the plurality of support pins 34 may be arranged at intervals of substantially 30°.

The upper side supply part 40 supplies a processing fluid from an upper side of a wafer W to a front surface of such a wafer W. The upper side supply part 40 has supply parts 41a to 41e, a nozzle 42a, a liquid supply nozzle 42b, a cleaning nozzle 42c, arms 43a, 43b, and driving units 44a, 44b.

A supply part 41a includes a liquid source, a valve, a pump, a heater, etc., that are not illustrated therein, and supplies various types of processing liquids downwardly from the nozzle 42a, based on a signal from the controller 3. For example, a processing liquid that is supplied from the supply part 41a is an SPM (a mixed liquid of sulfuric acid, hydrogen peroxide, and water), etc., and is at a temperature (for example, about 120° C.) that is higher than a room temperature.

A supply part 41b includes a liquid source, a valve, a pump, a heater, etc., that are not illustrated therein, and supplies a processing liquid for cleaning downwardly from the liquid supply nozzle 42b, based on a signal from the controller 3.

A processing liquid for cleaning that is supplied from the supply part 41b is an example of a liquid, and is, for example, SC1 (a mixed liquid of ammonia, hydrogen peroxide, and water), etc. A processing liquid for cleaning that is supplied from the supply part 41b is, for example, at a temperature (for example, 40° C. to 70° C.) that is higher than a room temperature.

A supply part 41c includes a liquid source, a valve, a pump, etc., that are not illustrated therein, and supplies a rinse liquid downwardly from the liquid supply nozzle 42b, based on a signal from the controller 3. A rinse liquid that is supplied from the supply part 41c is, for example, DIW (deionized water), etc. A rinse liquid that is supplied from the supply part 41c is, for example, at a room temperature.

A supply part 41d includes a liquid source, a valve, a pump, a heater, etc., that are not illustrated therein, and supplies a processing liquid for cleaning downwardly from the cleaning nozzle 42c, based on a signal from the controller 3.

A processing liquid for cleaning that is supplied from the supply part 41d is an example of a cleaning liquid, and is, for example, SC1, etc. A processing liquid for cleaning that is supplied from the supply part 41d is, for example, at a temperature (for example, 40° C. to 70° C.) that is higher than a room temperature.

A supply part 41e includes a gas source, a valve, a pump, etc., that are not illustrated therein, and supplies various types of processing gasses downwardly from the cleaning nozzle 42c, based on a signal from the controller 3. A processing gas that is supplied from the supply part 41e is an example of a gas, and is, for example, an inert gas such as a nitrogen gas.

For example, the nozzle 42a is a bar nozzle and is attached to an arm 43a. The arm 43a is positioned in a space at an upper side of the rotational holding part 30. A driving unit 44a lifts and lowers the arm 43a in upward and downward directions and rotates the arm 43a in a horizontal direction at an upper side of the rotational holding part 30, based on a signal from the controller 3.

The liquid supply nozzle 42b and the cleaning nozzle 42c are attached to an arm 43b and are configured to be movable integrally with one another. Furthermore, the liquid supply nozzle 42b and the cleaning nozzle 42c are positioned separately from one another by a predetermined distance (for example, 40 mm).

Thus, in an embodiment, the liquid supply nozzle 42b and the cleaning nozzle 42c are commonly attached to the arm 43b and are configured to be movable integrally with one another, so that a single driving system is sufficient and hence it is possible to reduce a cost of the substrate processing apparatus 1.

For example, the cleaning nozzle 42c is a two-fluid nozzle and mixes SC1 that is supplied from the supply part 41d and a processing gas that is supplied from the supply part 41e so as to discharge such a mixed processing fluid (that will also be called a mixed fluid M (see FIG. 7) below) to a front surface of a wafer W.

As illustrated in FIG. 1, the arm 43b is positioned in a space at an upper side of the rotational holding part 30. A driving unit 44b lifts and lowers the arm 43b in upward and downward directions and rotates the arm 43b in a horizontal direction at an upper side of the rotational holding part 30, based on a signal from the controller 3.

The lower side supply part 50 supplies a processing fluid from a lower side of a wafer W to a lower surface of such a wafer W, etc. The lower side supply part 50 has supply parts 51a, 51b, 52, and a back surface nozzle 53.

A supply part 51a includes a liquid source, a valve, a pump, a heater, etc., that are not illustrated therein, and supplies various types of processing liquids for cleaning upwardly from a first flow channel 53a of the back surface nozzle 53, based on a signal from the controller 3.

A processing liquid for cleaning that is supplied from the supply part 51a is an example of another liquid, and is, for example, SC1, etc. A processing liquid for cleaning that is supplied from the supply part 51a is, for example, at a temperature (for example, 40° C. to 70° C.) that is higher than a room temperature.

A supply part 51b includes a liquid source, a valve, a pump, a heater, etc., that are not illustrated therein, and supplies various types of rinse liquids upwardly from the first flow channel 53a of the back surface nozzle 53, based on a signal from the controller 3.

A rinse liquid that is supplied from the supply part 51b is, for example, DIW, etc. A rinse liquid that is supplied from the supply part 51b is, for example, at a room temperature or a temperature (for example, 40° C. to 70° C.) that is higher than such a room temperature.

A supply part 52 includes a gas source, a valve, a pump, etc., that are not illustrated therein, and supplies various types of processing gasses upwardly from a second flow channel 53b of the back surface nozzle 53, based on a signal from the controller 3. A processing gas that is supplied from the supply part 52 is, for example, an inert gas such as a nitrogen gas.

The cup body 60 is arranged so as to surround the substrate holding part 33 from an outside thereof and recovers a processing fluid that is scattered from a wafer W that is held by the substrate holding part 33. The cup body 60 has, for example, an inner cup 61, a drain cup 62, and an exhaust cup 63.

For example, the inner cup 61 has an ring shape, and is arranged so as to surround a wafer W in a state where it is supported by the plurality of support pins 34, from an outside thereof. The inner cup 61 is supported by, for example, an upper surface 33b of the substrate holding part 33. Hence, the inner cup 61 is rotated with rotation of the rotational shaft 31 around a central axis Ax of the rotational shaft 31.

Furthermore, a gap is present between the inner cup 61 and the substrate holding part 33, so that a processing fluid that is supplied to a wafer W flows to an outside of the inner cup 61 and the substrate holding part 33 through such a gap. Additionally, the inner cup 61 is not limited to a case where it is configured to be rotatable with the substrate holding part 33, and may be fixed on the processing chamber 20.

The drain cup 62 is positioned so as to surround the inner cup 61 from an outside thereof. The drain cup 62 forms a cylindrical space that is communicated with a gap between the inner cup 61 and the substrate holding part 33 so as to recover a processing liquid that flows out of such a gap. A pipe for draining a recovered processing liquid to a drain part DR that is positioned outside the substrate processing apparatus 1 is connected to a lower end part of the drain cup 62.

The exhaust cup 63 is positioned so as to surround the drain cup 62 from an outside thereof. The exhaust cup 63 forms a cylindrical space between it and the drain cup 62 and such a space is adjusted to a negative pressure. A pipe for suctioning an atmosphere near the inner cup 61 and exhausting it to an exhaust part EXH that is positioned outside the substrate processing apparatus 1 is connected to a lower end part of the exhaust cup 63.

The mist guard 70 is positioned so as to surround the cup body 60 from an outside thereof. That is, the substrate holding part 33 and the cup body 60 are positioned inside the mist guard 70. The mist guard 70 has, for example, a cylindrical part 71 and an overhang part 72.

For example, the cylindrical part 71 has a cylindrical shape and extends in upward and downward directions. For example, the overhang part 72 has a ring shape and extends in a horizontal direction from an upper end part of the cylindrical part 71 toward an inside in a radial direction (that is, at a cup body 60 side).

For example, the mist guard 70 is configured to be capable of being lifted and lowered by a non-illustrated lifting/lowering mechanism. Then, the controller 3 arranges the mist guard 70 at a high position, so that it is possible to reduce or prevent reaching of a mist of a processing liquid that is scattered from a wafer W that rotates to an inner wall of the processing chamber 20.

### Detail of Cleaning Process and Rinsing Process

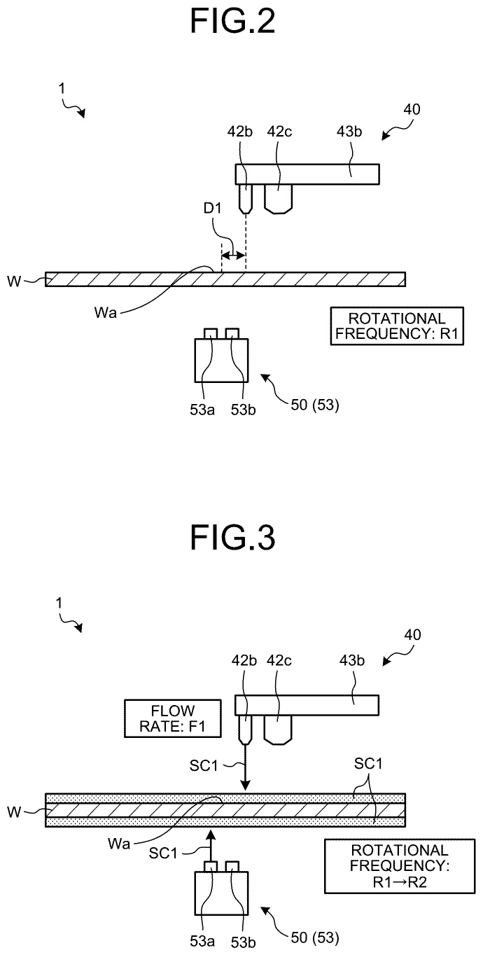

Next, a detail of a cleaning process and a rising process for a substrate processing apparatus 1 according to an embodiment will be explained with reference to FIG. 2 to FIG. 18. FIG. 2 to FIG. 11 are diagrams for explaining a cleaning process according to an embodiment.

Additionally, in the substrate processing apparatus 1, a controller 3 (see FIG. 1) executes, for example, a holding process, substrate processing, and a rising process, prior to a cleaning process and a rising process that will be explained later.

In a holding process, the controller 3 holds, by a rotational holding part 30 (see FIG. 1), a wafer W (see FIG. 1) that is transferred to an inside of a processing chamber 20 (see FIG. 1) through a carrying-in/out port by a substrate transfer device. In substrate processing, the controller 3 discharges SPM at a high temperature from a nozzle 42a (see FIG. 1) that is a bar nozzle to a front surface of a wafer W, so as to execute a liquid process for a whole of a front surface of such a wafer W.

In a rinsing process, the controller 3 discharges DIW as a rinse liquid from a liquid supply nozzle 42b (see FIG. 1) and a back surface nozzle 53 (see FIG. 1) to a front surface and a back surface of a wafer W so as to execute a rinsing process for such a wafer W. For example, a state around a wafer W where a previous process has been ended is a state as illustrated in FIG. 2.

In a cleaning process of the substrate processing apparatus 1 according to an embodiment, first, the controller 3 (see FIG. 1) operates an upper side supply part 40 so as to move the liquid supply nozzle 42b to a predetermined position as illustrated in FIG. 2. Specifically, the controller 3 moves the liquid supply nozzle 42b to an upper side of a central part of a wafer W that is separated from a center Wa of such a wafer W by a predetermined distance D1 (for example, 15 mm). Additionally, a center Wa of a wafer W is an example of a central part of such a wafer W.

Furthermore, in a state as illustrated in FIG. 2, the controller 3 rotates a wafer W that is held by the rotational holding part 30 (see FIG. 1) at a predetermined rotational frequency R1 (for example, 500 rpm).

Additionally, none of a processing liquid and a processing gas is discharged from any of the liquid supply nozzle 42b, a cleaning nozzle 42c, and the back surface nozzle 53 herein. On the other hand, in the present disclosure, the controller 3 may continue to discharge a processing gas (for example, a nitrogen gas, etc.) at a low flow rate (for example, 2 L/min) constantly from a second flow channel 53b of the back surface nozzle 53, although no illustration thereof is provided in a subsequent drawing(s).

Thereby, it is possible to reduce or prevent a backward flow of various types of processing liquids that are discharged to a back surface of a wafer W to the second flow channel 53b in a subsequent cleaning process and rinsing process. Therefore, according to an embodiment, it is possible to reduce or prevent contaminating of a wafer W with a processing liquid that flows backward, when a processing gas for drying is discharged from the second flow channel 53b of the back surface nozzle 53 in a drying process after a rinsing process.

Then, the controller 3 (see FIG. 1) changes a rotational frequency (increases a rotational frequency) of a wafer W from a rotational frequency R1 to a predetermined rotational frequency R2 (for example, 1500 rpm) as illustrated in FIG. 3.

Furthermore, the controller 3 discharges SC1 that is at a predetermined flow rate F1 (for example, 1500 mL/min) and a temperature (for example, 40° C. to 70° C.) that is higher than a room temperature, from the liquid supply nozzle 42b to a front surface of a wafer W. Thereby, the controller 3 forms a liquid film of SC1 on a front surface of a wafer W.

Moreover, the controller 3 discharges Sc1 that is at a predetermined flow rate (for example, 1000 mL/min) and a temperature (for example, 40° C. to 70° C.) that is higher than a room temperature, from a first flow channel 53a of the back surface nozzle 53 to a back surface of a wafer W. Such SC1 that is discharged to a back surface thereof is spread over a whole of a back surface of a wafer W.

Thus, in an embodiment, Sc1 at a temperature that is higher than a room temperature is discharged from the back surface nozzle 53 to a back surface of a wafer W, so that it is possible to maintain such a wafer W at a temperature that is higher than a room temperature. Therefore, according to an embodiment, it is possible to execute a subsequent cleaning process under a high temperature efficiently.

Furthermore, in an embodiment, a rotational frequency of a wafer W is changed to a rotational frequency R2 that is a high speed in such a process in FIG. 3, so that it is possible to spread SC1 at a temperature that is higher than a room temperature over a front surface and a back surface of such a wafer W quickly. Therefore, according to an embodiment, it is possible to raise a temperature of a wafer W quickly, so that it is possible to transfer to a subsequent process quickly.

Furthermore, in an embodiment, SC1 at a high temperature is discharged from the liquid supply nozzle 42b to a position that is separated from a center Wa by a predetermined distance D1 (see FIG. 2) in such a process in FIG. 3, so that it is possible to equalize a temperature of a central part of a wafer W more effectively than a case where such SC1 at a high temperature is directly discharged to such a center Wa.

In other words, it is possible to provide a temperature distribution of a wafer W that is bimodal by discharging SC1 at a high temperature to a position that is separated from a center Wa by a predetermined distance D1 whereas such a temperature distribution of a wafer W is unimodal in a case where such SC1 at a high temperature is directly discharged to such a center Wa.

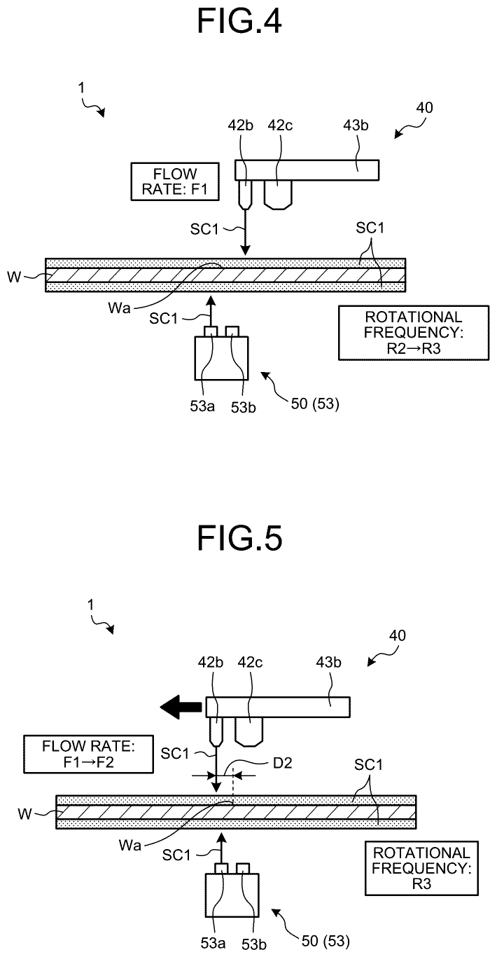

Then, the controller 3 (see FIG. 1) changes a rotational frequency (decreases a rotational frequency) of a wafer W from a rotational frequency R2 to a predetermined rotational frequency R3 (for example, 200 rpm) while discharge of SC1 from the liquid supply nozzle 42b and the back surface nozzle 53 is maintained, as illustrated in FIG. 4.

Then, the controller 3 (see FIG. 1) changes a discharge rate (decreases a flow rate) of SC1 from the liquid supply nozzle 42b from a flow rate F1 to a predetermined flow rate F2 (for example, 450 mL/min) while discharge of SC1 from the back surface nozzle 53 is maintained, as illustrated in FIG. 5.

Furthermore, the controller 3 operates the upper side supply part 40 so as to move the liquid supply nozzle 42b and the cleaning nozzle 42c to predetermined positions. Specifically, the controller 3 moves the liquid supply nozzle 42b to an upper side of a central part of a wafer W that is separated from a center Wa of such a wafer W by a predetermined distance D2 (for example, 20 mm).

Thereby, the controller 3 substantially equalizes a distance from the liquid supply nozzle 42b to a center Wa of a wafer W and a distance from the cleaning nozzle 42c to such a center Wa of a wafer W.

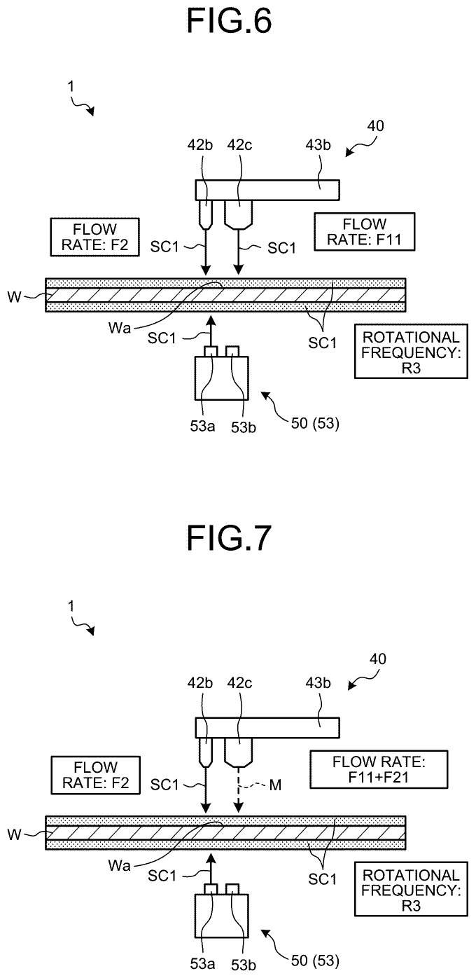

Then, the controller 3 (see FIG. 1) discharges SC1 at a predetermined flow rate F11 (for example, 100 mL/min) from the cleaning nozzle 42c to a front surface of a wafer W while discharge of SC1 from the liquid supply nozzle 42b and the back surface nozzle 53 is maintained, as illustrated in FIG. 6. Additionally, SC1 that is discharged from the cleaning nozzle 42c is at a temperature (for example, 40° C. to 70° C.) that is higher than a room temperature.

Herein, in an embodiment, a distance from the liquid supply nozzle 42b to a center Wa and a distance from the cleaning nozzle 42c to such a center Wa are substantially equalized in a process in FIG. 5 as described above, so that it is possible to reduce or prevent a liquid splash on a wafer W at a time when SC1 is discharged from the cleaning nozzle 42c.

That is because a momentum of Sc1 that is discharged to a position that is shifted from a center Wa and is spread over a front surface of a wafer W is reduced just below the cleaning nozzle 42c as compared with a case where it is discharged to such a center Wa of such a wafer W.

Then, the controller 3 (see FIG. 1) discharges a processing gas at a predetermined flow rate F21 (for example, 20 L/min) from the cleaning nozzle 42c to a front surface of a wafer W while discharge of SC1 from the liquid supply nozzle 42b, the back surface nozzle 53, and the cleaning nozzle 42c is maintained, as illustrated in FIG. 7. A flow rate F21 is an example of a first flow rate.

Thereby, a mixed fluid M where SC1 and a processing gas are mixed is discharged from the cleaning nozzle 42c to a front surface of a wafer W.

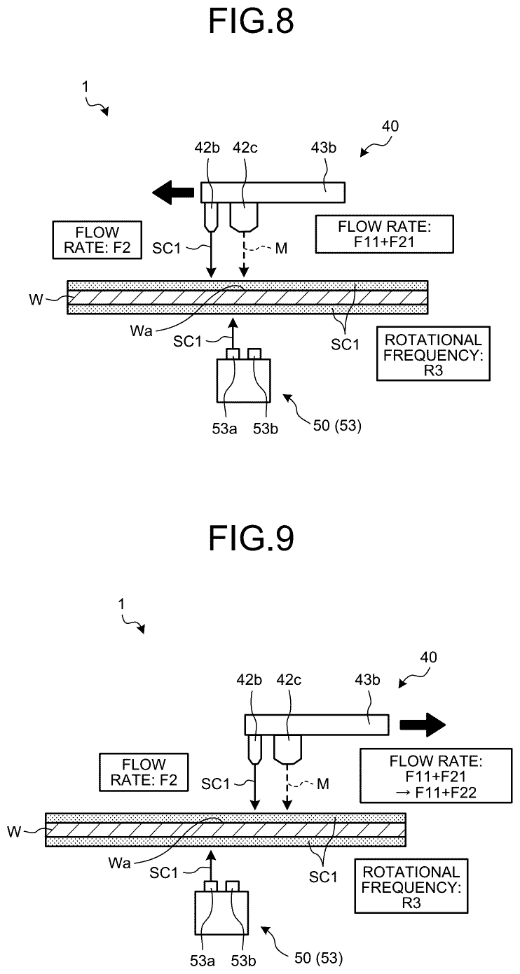

Then, the controller 3 (see FIG. 1) operates the upper side supply part 40 so as to move the cleaning nozzle 42c to an upper side of a center Wa of a wafer W while discharge of SC1 and a mixed fluid M from the liquid supply nozzle 42b, the back surface nozzle 53, and the cleaning nozzle 42c is maintained, as illustrated in FIG. 8.

Then, the controller 3 (see FIG. 1) changes a discharge rate (increases a flow rate) of a processing gas from the cleaning nozzle 42c from a flow rate F21 to a predetermined flow rate F22 (for example, 60 L/min) while discharge of a mixed fluid M from the cleaning nozzle 42c is maintained, as illustrated in FIG. 9. A flow rate F22 is an example of a second flow rate.

Then, simultaneously with increasing a discharge rate of a processing gas, the controller 3 operates the upper side supply part 40 so as to move the cleaning nozzle 42c from an upper side of a center Wa of a wafer W to a peripheral part of such a wafer W and execute a cleaning process for a front surface of such a wafer W with a mixed fluid M, as illustrated in FIG. 9.

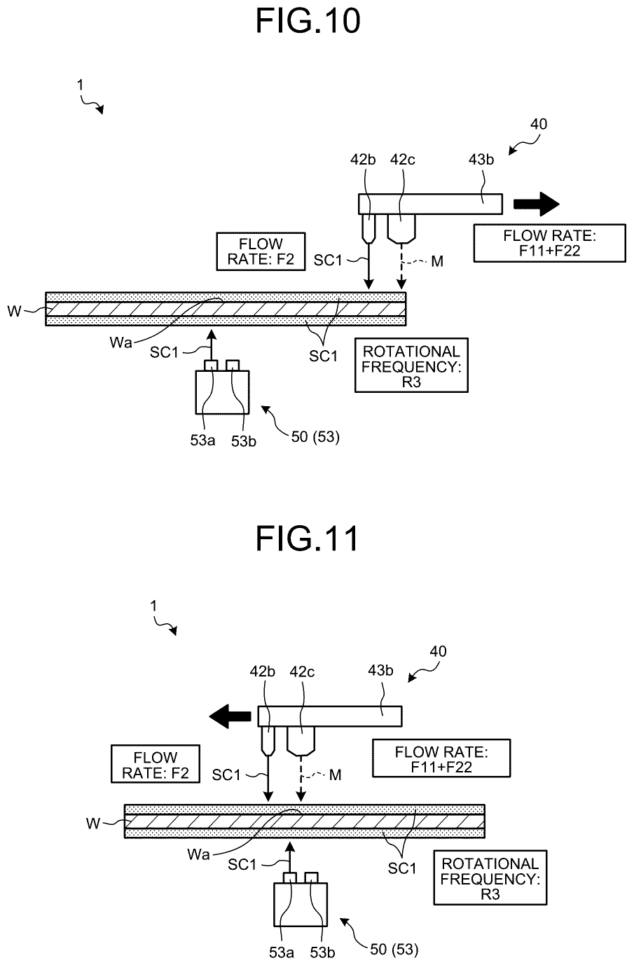

Moreover, after the cleaning nozzle 42c reaches an upper side of a peripheral part of a wafer W as illustrated in FIG. 10, the controller 3 (see FIG. 1) moves the cleaning nozzle 42c to an upper side of a central part (a center Wa) of such a wafer Was illustrated in FIG. 11, and repeats a cleaning process for such a wafer W with a mixed fluid M.

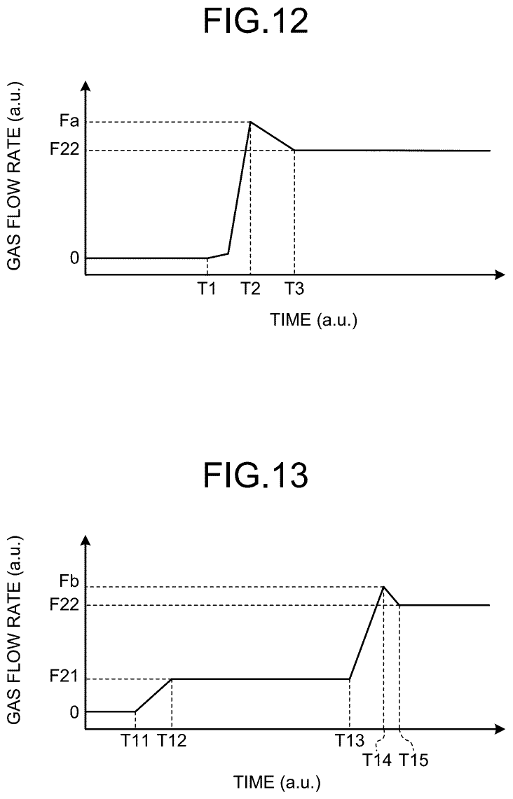

Herein, in an embodiment, when a cleaning process for a wafer W with a mixed fluid M is executed, it is preferable that discharge of a processing gas is first started at a low flow rate F21, then it is increased to a flow rate F22 for a cleaning process, and subsequently such a cleaning process for a wafer W is started. A reason thereof will be explained with reference to FIG. 12 and FIG. 13.

FIG. 12 is a diagram that illustrates an example of a transition of a flow rate of a processing gas that is discharged from the cleaning nozzle 42c in a cleaning process in a reference example. In such a reference example, the controller 3 (see FIG. 1) instructs a supply part 41e (see FIG. 1) to start discharge of a processing gas at a high flow rate F22 for a cleaning process at a time T1.

Thus, in a reference example, it attempts to cause a processing gas to flow at a high flow rate F22 suddenly from a flow rate of zero, so that a flow rate of a gas rises rapidly and such a flow rate of a gas overshoots to a flow rate Fa that is considerably greater than such a flow rate F22 at a time T2. Subsequently, a valve, etc., of the supply part 41e function so as to reduce such overshoot, so that a processing gas is discharged at a specified flow rate F22 from a time T3.

Then, in a reference example, a flow rate of a gas is thus large so as to cause overshoot and such overshot processing gas is discharged to a liquid film on a wafer W, so that a splash of a large amount of a liquid may occur on such a wafer W. Then, each nozzle may be contaminated with such a splash of a large amount of a liquid on a wafer W so as to generate a large number of particles on such a wafer W.

FIG. 13 is a diagram that illustrates an example of a transition of a flow rate of a processing gas that is discharged from the cleaning nozzle 42c in a cleaning process according to an embodiment. As illustrated in FIG. 13, in an embodiment, the controller 3 (see FIG. 1) instructs the supply part 41e (see FIG. 1) to start discharge of a processing gas at a flow rate F21 that is less than that for a cleaning process at a time T11. Thereby, a processing gas is discharged at a specified flow rate F21 from a time T12.

Then, the controller 3 instructs the supply part 41e to start discharge of a processing gas at a high flow rate F22 for a cleaning process at a time T13. In such a case, a processing gas at a flow rate F21 is already discharged from the cleaning nozzle 42c, so that overshoot that occurs before reaching a specified flow rate F22 at a time T15 is less than overshoot in a reference example.

In other words, in a cleaning process according to an embodiment, a flow rate Fb that is a local maximum value of a flow rate of a processing gas at a time T14 before reaching a flow rate F22 for a cleaning process is less than a flow rate Fa (see FIG. 12) that is a local maximum value of a flow rate of a processing gas in a reference example.

Therefore, according to an embodiment, even in a case where a processing gas at a predetermined flow rate F22 is discharged from the cleaning nozzle 42c to a liquid film on a wafer W in order to execute a cleaning process with a mixed fluid M (see FIG. 9), it is possible to reduce or prevent occurring of a liquid splash on such a wafer W.

Additionally, in a cleaning process according to an embodiment, the controller 3 may execute only-one-round scanning of the cleaning nozzle 42c between a central part (a center Wa) and a peripheral part of a wafer W or may execute multiple-round scanning thereof between such a central part (a center Wa) and a peripheral part of a wafer W. In any case, when a cleaning process according to an embodiment is ended, the controller 3 positions the cleaning nozzle 42c at an upper side of a central part (a center Wa) of a wafer W as illustrated in FIG. 11.

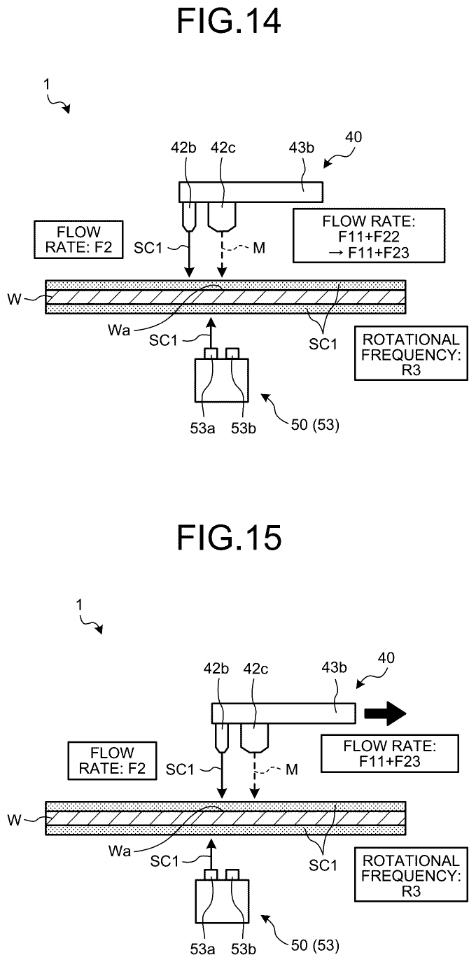

After a cleaning process as has been explained above is ended, the controller 3 continuously executes a rinsing process for a wafer W. FIG. 14 to FIG. 18 are diagrams for explaining a rising process according to an embodiment.

In a rising process according to an embodiment, first, the controller 3 (see FIG. 1) changes a discharge rate of a processing gas from the cleaning nozzle 42c from a flow rate F22 to a predetermined flow rate F23 while discharge of a mixed fluid M from the cleaning nozzle 42c is maintained, as illustrated in FIG. 14. A flow rate F23 is an example of a third flow rate. A flow rate F23 is a value that is less than a flow rate F22 and is, for example, 20 L/min.

Thereby, a mixed fluid M that is produced by a processing gas at a high flow rate F22 is continued to be discharged to a central part of a wafer W, so that it is possible to reduce or prevent damaging (collapse, etc.) of a structure such as a pattern of a semiconductor device that is formed on a central part (for example, a center Wa) of a wafer W.

Then, the controller 3 (see FIG. 1) moves the liquid supply nozzle 42b to an upper side of a central part (a center Wa) of a wafer W while discharge of SC1 and a mixed fluid M from the liquid supply nozzle 42b, the back surface nozzle 53, and the cleaning nozzle 42c is maintained, as illustrated in FIG. 15.

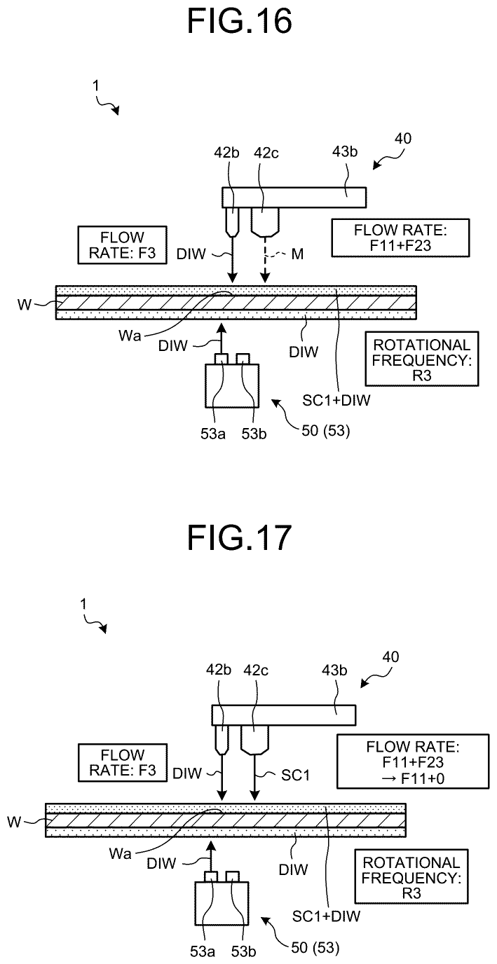

Then, the controller 3 (see FIG. 1) discharges DIW at a room temperature and a predetermined flow rate F3 (for example, 450 mL/min) from the liquid supply nozzle 42b to a front surface side of a central part (a center Wa) of a wafer W, as illustrated in FIG. 16. Thereby, the controller 3 executes a rinsing process with DIW for a front surface of a wafer W.

Moreover, the controller 3 discharges DIW at a room temperature and a predetermined flow rate (for example, 1500 mL/min) from the first flow channel 53a of the back surface nozzle 53 to a back surface of a wafer W. Thereby, the controller 3 executes a rinsing process with DIW for a back surface of a wafer W.

Additionally, as illustrated in FIG. 16, discharge of a mixed fluid M from the cleaning nozzle 42c is continued when discharge of DIW from the liquid supply nozzle 42b and the back surface nozzle 53 is started. Herein, for a mixed fluid M, a discharge rate of SC1 is a flow rate F11 and a discharge rate of a processing gas is a flow rate F23.

Thus, in an embodiment, discharge of a mixed fluid M from the cleaning nozzle 42c may be maintained before discharge of a rinse liquid (DIW) from the liquid supply nozzle 42b is started. Thereby, it is possible to continue to form a liquid film on a whole of a front surface of a wafer W after discharge of a mixed fluid M is stopped, as compared with a case where a processing liquid that is discharged from the liquid supply nozzle 42b is switched from SC1 to DIW.

Therefore, according to an embodiment, at least a part of a front surface of a wafer W is dried when transfer from a cleaning process to a rinsing process is executed, so that it is possible to reduce or prevent attaching of a particle(s) to such a wafer W.

Then, the controller 3 (see FIG. 1) stops discharge of a processing gas from the cleaning nozzle 42c (that is, a discharge or flow rate of a processing gas=0) while discharge of DIW from the liquid supply nozzle 42b and the back surface nozzle 53 is maintained, as illustrated in FIG. 17. Thereby, the controller 3 discharges only SC1 from the liquid supply nozzle 42b.

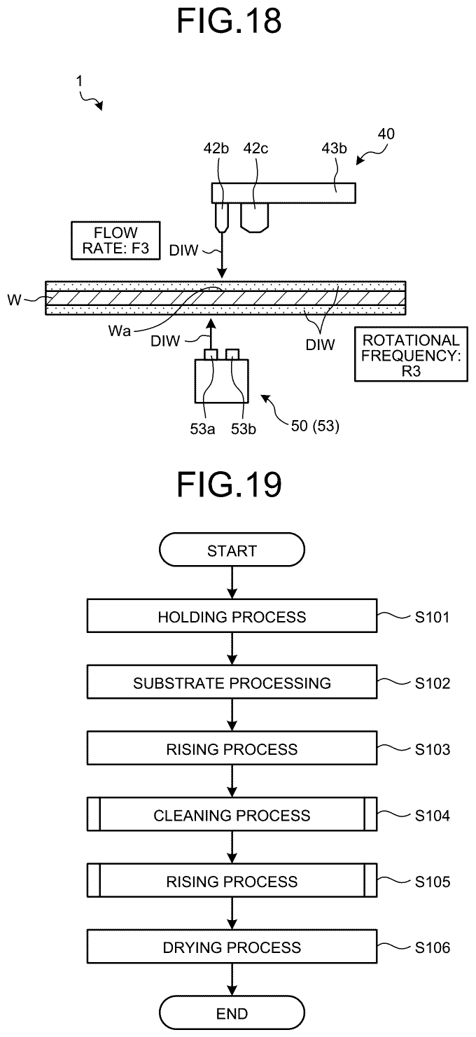

Then, the controller 3 (see FIG. 1) stops discharge of SC1 from the cleaning nozzle 42c while discharge of DIW from the liquid supply nozzle 42b and the back surface nozzle 53 is maintained, as illustrated in FIG. 18. Thereby, only DIW that is a rinse liquid is supplied to a front surface of a wafer W.

Thus, in an embodiment, the controller 3 may first stop discharge of a processing gas and then stop discharge of SC1 when discharge of a mixed fluid M from the cleaning nozzle 42c is stopped. Thereby, it is possible to continue to form a liquid film on a whole of a front surface of a wafer W after discharge of SC1 is stopped, as compared with a case where discharge of a processing gas is started.

Therefore, according to an embodiment, at least a part of a front surface of a wafer W is dried when transfer from a cleaning process to a rinsing process is executed, so that it is possible to reduce or prevent attaching of a particle(s) to such a wafer W.

Subsequent to a process as illustrated in FIG. 18, the controller 3 increases a discharge rate of DIW from the liquid supply nozzle 42b, increases a rotational frequency of a wafer W, etc., so as to execute a rising process for such a wafer W (non-illustrated).

Furthermore, for a wafer W where a rising process is ended, the controller 3 controls the rotational holding part 30, etc., so as to execute a drying process with spin drying for such a wafer W (non-illustrated). Additionally, in such a drying process, the controller 3 may discharge a processing gas at a predetermined flow rate (for example, 2 L/min) from the second flow channel 53b of the back surface nozzle 53.

Then, as a drying process for a wafer W is ended, a series of substrate processing in the substrate processing apparatus 1 is ended.

A substrate processing apparatus 1 according to an embodiment includes a rotational holding part 30, a cleaning nozzle 42c, a liquid supply nozzle 42b, and a controller 3. The rotational holding part 30 holds a substrate (a wafer W) rotatably. The cleaning nozzle 42c is provided movably at an upper side of the substrate (the wafer W) that is heled by the rotational holding part 30 and rotates, from a central part to a peripheral part of the substrate (the wafer W), and discharges a mixed fluid M of a cleaning liquid (SC1) and a gas onto the substrate (the wafer W). The liquid supply nozzle 42b is provided movably at an upper side of the substrate (the wafer W), integrally with the cleaning nozzle 42c, and discharges a liquid (SC1) onto the substrate (the wafer W). The controller 3 controls each part. The cleaning nozzle 42c is capable of discharging each of the cleaning liquid (SC1) and the gas independently. The controller 3 executes a first process, a second process, a third process, and a fourth process. The first process discharges the liquid (SC1) from the liquid supply nozzle 42b to a central part of the substrate (the wafer W) so as to form a liquid film of the liquid (SC1) on the substrate (the wafer W). The second process discharges the cleaning liquid (SC1) from the cleaning nozzle 42c to a central part of the substrate (the wafer W) on the substrate (the wafer W) where a liquid film of the liquid (SC1) has been formed. The third process discharges the gas at a first flow rate (a flow rate F21) from the cleaning nozzle 42c onto the substrate (the wafer W) so as to discharge the mixed fluid M to a central part of the substrate (the wafer W). The fourth process moves the cleaning nozzle 42c that discharges the mixed fluid M and the liquid supply nozzle 42b that discharges the liquid (SC1) from an upper side of a central part to an upper side of a peripheral part of the substrate (the wafer W) while changing a flow rate of the gas that is discharged from the cleaning nozzle 42c to a second flow rate (a flow rate F22) that is greater than the first flow rate. Thereby, it is possible to reduce or prevent occurring of a liquid splash on a wafer W in a cleaning process with a mixed fluid M.

Furthermore, in the substrate processing apparatus 1 according to an embodiment, the controller 3 further executes a fifth process and a sixth process. The fifth process moves the cleaning nozzle 42c and the liquid supply nozzle 42b from an upper side of a peripheral part to an upper side of a central part of the substrate (the wafer W) while discharging the mixed fluid M from the cleaning nozzle 42c and discharging the liquid (SC1) from the liquid supply nozzle 42b after the cleaning nozzle 42c reaches an upper side of a peripheral part of the substrate (the wafer W). The sixth process discharges a rinse liquid (DIW) from the liquid supply nozzle 42b that has moved to an upper side of a central part of the substrate (the wafer W) to the substrate (the wafer W). Thereby, at least a part of a front surface of a wafer W is dried when transfer from a cleaning process to a rising process is executed, so that it is possible to reduce or prevent attaching of a particle(s) to such a wafer W.

Furthermore, in the substrate processing apparatus 1 according to an embodiment, the controller 3 further executes a seventh process. The seventh process first stops discharge of the gas and then stops discharge of the cleaning liquid (SC1) in the cleaning nozzle 42c, after starting the sixth process. Thereby, at least a part of a front surface of a wafer W is dried when transfer from a cleaning process to a rising process is executed, so that it is possible to reduce or prevent attaching of a particle(s) to such a wafer W.

Furthermore, in the substrate processing apparatus 1 according to an embodiment, the controller 3 further executes a fifth process and an eighth process. The fifth process moves the cleaning nozzle 42c and the liquid supply nozzle 42b from an upper side of a peripheral part to an upper side of a central part of the substrate (the wafer W) while discharging the mixed fluid M from the cleaning nozzle 42c and discharging the liquid (SC1) from the liquid supply nozzle 42b after the cleaning nozzle 42c reaches an upper side of a peripheral part of the substrate (the wafer W). The eighth process changes a flow rate of the gas that is discharged from the cleaning nozzle 42c that has moved to an upper side of a central part of the substrate (the wafer W) to a third flow rate (a flow rate F23) that is less than the second flow rate (the flow rate F22). Thereby, it is possible to reduce or prevent collapsing of a pattern of a semiconductor device that is formed on a central part of a wafer W, etc.

Furthermore, the substrate processing apparatus 1 according to an embodiment further includes a back surface nozzle 53 that discharges another liquid (SC1) to a back surface of the substrate (the wafer W) that is held by the rotational holding part 30. Furthermore, the controller 3 further executes a ninth process. The ninth process discharges the another liquid (SC1) at a temperature that is higher than a room temperature from the back surface nozzle 53 to a back surface of the substrate (the wafer W) when executing the fourth process. Thereby, it is possible to execute a cleaning process under a high temperature efficiently.

### Procedure of Substrate Processing

Next, a procedure of substrate processing for a substrate processing apparatus 1 according to an embodiment will be explained with reference to FIG. 19 to FIG. 22. FIG. 19 is a flowchart that illustrates an example of a procedure of substrate processing that is executed by the substrate processing apparatus 1 according to an embodiment.

In substrate processing according to an embodiment, first, a controller 3 controls a substrate transfer device, etc., so as to carry a wafer W in an inside of a processing chamber 20 through a carrying-in/out port of the processing chamber 20 and hold it by a rotational holding part 30 (step S101).

Then, the controller 3 controls an upper side supply part 40, etc., so as to discharge SPM at a high temperature from a nozzle 42a to a front surface of a wafer W and execute substrate processing for such a wafer W (step S102). Then, the controller 3 controls the upper side supply part 40, a lower side supply part 50, etc., so as to discharge DIW from a liquid supply nozzle 42b and a back surface nozzle 53 to both surfaces of a wafer W and execute a rinsing process for such a wafer W (step S103).

Then, the controller 3 controls, the upper side supply part 40, the lower side supply part 50, etc., so as to execute a cleaning process for a wafer W (step S104). A detail of such a cleaning process will be described later.

Then, the controller 3 controls the upper side supply part 40, the lower side supply part 50, etc., so as to execute a rinsing process for a wafer W (step S105). A detail of such a rinsing process will be described later.

Finally, the controller 3 controls the rotational holding part 30, etc., so as to execute a drying process with spin drying, etc., for a wafer W (step S106), and end a series of substrate processing.

Additionally, in the present disclosure, substrate processing that is executed prior to processes at steps S104 and S105 is not limited to substrate processing with SPM, etc., and various types of substrate processing may be executed. Furthermore, in the present disclosure, for a wafer W where substrate processing thereof has been executed by another substrate processing apparatus, only processes at steps S104 to S106 may be executed in the substrate processing apparatus 1.

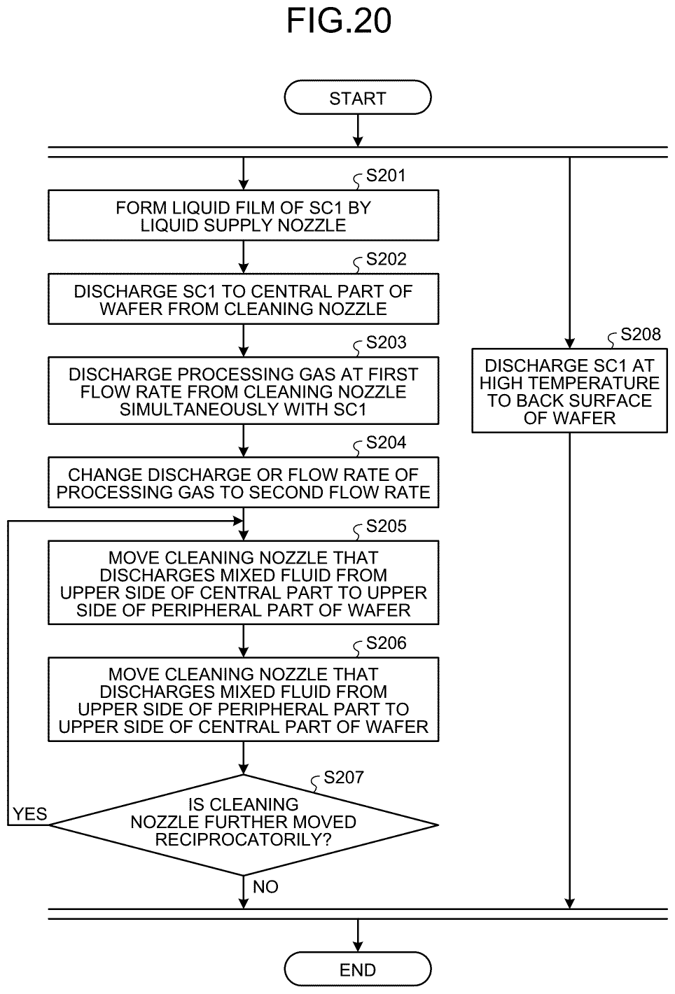

FIG. 20 is a flowchart that illustrates an example of a procedure of a cleaning process that is executed by the substrate processing apparatus 1 according to an embodiment. In a cleaning process according to an embodiment, first, the controller 3 controls the upper side supply part 40, etc., so as to discharge SC1 from the liquid supply nozzle 42b to a central part of a front surface of a wafer W and form a liquid film of SC1 on such a front surface of a wafer W by the liquid supply nozzle 42b (step S201). Such a process at S201 is an example of a first process.

Then, the controller 3 controls the upper side supply part 40, etc., so as to discharge SC1 from a cleaning nozzle 42c to a central part of a front surface of a wafer W (step S202). Such a process at S202 is an example of a second process.

Then, the controller 3 controls the upper side supply part 40, etc., so as to discharge a processing gas at a first flow rate (a flow rate F21) from the cleaning nozzle 42c to a central part of a front surface of a wafer W simultaneously with SC1. Thereby, the controller 3 discharges a mixed fluid M to a central part of a front surface of a wafer W (step S203). Such a process at S203 is an example of a third process.

Then, the controller 3 controls the upper side supply part 40, etc., so as to change a discharge or flow rate of a processing gas from the cleaning nozzle 42c to a second flow rate (a flow rate F22) that is greater than a first flow rate (a flow rate F21) (step S204).

Then, the controller 3 moves the cleaning nozzle 42c that discharges a mixed fluid M where a discharge or flow rate of a processing gas has been changed to a second flow rate (a flow rate F22), from an upper side of a central part to an upper side of a peripheral part of a wafer W (step S205). Such processes at steps S204 and S205 are an example of a fourth process.

Then, the controller 3 controls the upper side supply part 40, etc., so as to move the cleaning nozzle 42c that discharges a mixed fluid M, from an upper side of a peripheral part to an upper side of a central part of a wafer W (step S206). Such a process at S206 is an example of a fifth process.

Then, the controller 3 determines whether or not the cleaning nozzle 42c that discharges a mixed fluid M is further moved reciprocatorily at an upper side of a wafer W (step S207). Then, in a case where it is determined that the cleaning nozzle 42c is further moved reciprocatorily at an upper side of a wafer W (step S207, Yes), returning to a process at step S205 is executed.

On the other hand, in a case where it is determined that the cleaning nozzle 42c is not further moved reciprocatorily at an upper side of a wafer W (step S207, No), a series of a cleaning process is ended.

Additionally, in parallel with processes at steps S201 to S207 as has been described above, the controller 3 controls the lower side supply part 50, etc., so as to discharge SC1 at a high temperature from the back surface nozzle 53 to a central part of a back surface of a wafer W (step S208). Such a process at step S208 is an example of a ninth process.

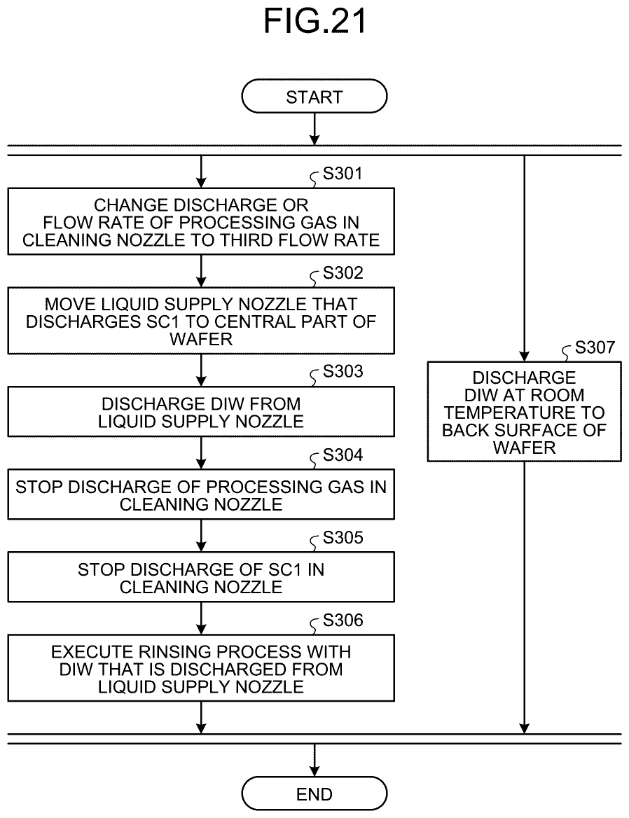

FIG. 21 is a flowchart that illustrates an example of a procedure of a rising process that is executed by the substrate processing apparatus 1 according to an embodiment. In a rising process according to an embodiment, first, the controller 3 controls the upper side supply part 40, etc., so as to change a discharge or flow rate of a processing gas in the cleaning nozzle 42c to a third flow rate (a flow rate F23) that is less than a second flow rate (step S301). Such a process at S301 is an example of an eighth process.

Then, the controller 3 controls the upper side supply part 40, etc., so as to move the liquid supply nozzle 42b that discharges SC1 to a central part (a center Wa) of a wafer W (step S302). Then, the controller 3 controls the upper side supply part 40, etc., so as to discharge DIW at a room temperature that is a rinse liquid from the liquid supply nozzle 42b (step S303). Such a process at S303 is an example of a sixth process.

Then, the controller 3 controls the upper side supply part 40, etc., so as to stop discharge of a processing gas in the cleaning nozzle 42c that discharges a mixed fluid M (step S304). Then, the upper side supply part 40, etc., are controlled so as to stop, in the cleaning nozzle 42c that discharges SC1, such discharge of SC1 (step S305). Such processes at steps S304 and S305 are an example of a seventh process.

Finally, the controller 3 controls the upper side supply part 40, etc., so as to execute a rinsing process for a wafer W with DIW at a room temperature that is discharged from the liquid supply nozzle 42b (step S306), and end a series of a rinsing process.

Additionally, in parallel with processes at steps S301 to S306 as has been explained above, the controller 3 controls the lower side supply part 50, etc., so as to discharge DIW at a room temperature from the back surface nozzle 53 to a central part of a back surface of a wafer W (step S307).

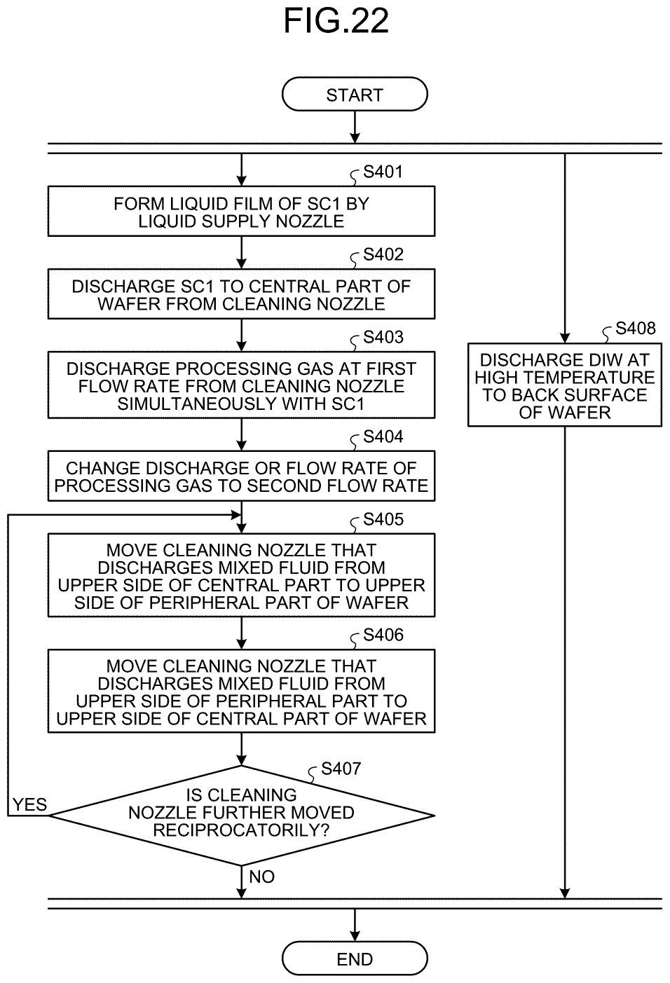

FIG. 22 is a flowchart that illustrates another example of a procedure of a cleaning process that is executed by the substrate processing apparatus 1 according to an embodiment. In a cleaning process according to another example, a liquid process for a back surface of a wafer W that is illustrated as a process at step S208 in FIG. 20 is different from an example of FIG. 20.

Additionally, other processes at steps S401 to S407 are similar to processes at steps S201 to S207 as illustrated in FIG. 20, so that a detailed explanation thereof will be omitted.

In a cleaning process according to another example, in parallel with such processes at steps S401 to S407, the controller 3 controls the lower side supply part 50, etc., so as to discharge DIW at a high temperature from the back surface nozzle 53 to a central part of a back surface of a wafer W (step S408). Such a process at S408 is another example of a ninth process.

Thus, in another example, DIW that is more inexpensive than SC1 is discharged to a back surface of a wafer W so as to raise a temperature of a back surface side of such a wafer W. Thereby, it is possible to execute a cleaning process under a high temperature efficiently at low cost.

A substrate processing method according to an embodiment includes a first step (step S201), a second step (step S202), a third step (step S203), and a fourth step (steps S204, S205). The first step (step S201) discharges a liquid (SC1) from a liquid supply nozzle 42b to a central part of a substrate (a wafer W) that rotates so as to form a liquid film of the liquid (SC1) on the substrate (the wafer W). The second step (step S202) discharges a cleaning liquid (SC1) from a cleaning nozzle 42c to a central part of the substrate (the wafer W) on the substrate (the wafer W) where a liquid film of the liquid (SC1) has been formed. The third step (step S203) discharges a gas at a first flow rate (a flow rate F21) from the cleaning nozzle 42c onto the substrate (the wafer W) so as to discharge a mixed fluid M of the cleaning liquid (SC1) and the gas to a central part of the substrate (the wafer W). The fourth step (steps S204, S205) moves the cleaning nozzle 42c that discharges the mixed fluid M and the liquid supply nozzle 42b that discharges the liquid (SC1) from an upper side of a central part to an upper side of a peripheral part of the substrate (the wafer W) while changing a flow rate of the gas that is discharged from the cleaning nozzle 42c to a second flow rate (a flow rate F22) that is greater than the first flow rate (the flow rate F21). Thereby, it is possible reduce or prevent occurring of a liquid splash on a wafer W in a cleaning process with a mixed fluid M.

Furthermore, the substrate processing method according to an embodiment further includes a fifth step (step S206) and a sixth step (step S303). The fifth step (step S206) moves the cleaning nozzle 42c and the liquid supply nozzle 42b from an upper side of a peripheral part to an upper side of a central part of the substrate (the wafer W) while discharging the mixed fluid M from the cleaning nozzle 42c and discharging the liquid (SC1) from the liquid supply nozzle 42b after the cleaning nozzle 42c reaches an upper side of a peripheral part of the substrate (the wafer W). The sixth step (step S303) discharges a rinse liquid (DIW) from the liquid supply nozzle 42b that has moved to an upper side of a central part of the substrate (the wafer W) to the substrate (the wafer W). Thereby, at least a part of a front surface of a wafer W is dried when transfer from a cleaning process to a rinsing process is executed, so that it is possible to reduce or prevent attaching of a particle(s) to such a wafer W.

Furthermore, the substrate processing method according to an embodiment further includes a seventh step (steps S304, S305). The seventh step (steps S304, S305) first stops discharge of the gas and then stops discharge of the cleaning liquid (SC1) in the cleaning nozzle 42c after starting the sixth step (step S306). Thereby, at least a part of a front surface of a wafer W is dried when transfer from a cleaning process to a rinsing process is executed, so that it is possible to reduce or prevent attaching of a particle(s) to such a wafer W.

Furthermore, the substrate processing method according to an embodiment further includes a fifth step (step S206) and an eighth step (S301). The fifth step (step S206) moves the cleaning nozzle 42c and the liquid supply nozzle 42b from an upper side of a peripheral part to an upper side of a central part of the substrate (the wafer W) while discharging the mixed fluid M from the cleaning nozzle 42c and discharging the liquid (SC1) from the liquid supply nozzle 42b after the cleaning nozzle 42c reaches an upper side of a peripheral part of the substrate (the wafer W). The eighth step (step S301) changes a flow rate of the gas that is discharged from the cleaning nozzle 42c that has moved to an upper side of a central part of the substrate (the wafer W) to a third flow rate (a flow rate F23) that is less than the second flow rate (the flow rate F22). Thereby, it is possible to reduce or prevent collapsing of a pattern of a semiconductor device that is formed on a central part of a wafer W, etc.

Furthermore, the substrate processing method according to an embodiment further includes a ninth step (step S208). The ninth step (step S208) discharges another liquid (SC1) at a temperature that is higher than a room temperature from a back surface nozzle 53 to a back surface of the substrate (the wafer W) when executing the fourth step (steps S204, S205). Thereby, it is possible to execute a cleaning process under a high temperature efficiently.

Although an embodiment(s) of the present disclosure has/have been explained above, the present disclosure is not limited to an embodiment(s) as described above and it is possible to execute a variety of modifications without departing from an essence thereof. For example, although an example where SC1 is used as a cleaning liquid that is one of raw materials of a mixed fluid M has been illustrated in an embodiment(s) as described above, such one of raw materials of a mixed fluid M is not limited to SC1 and it is possible to use various types of cleaning liquids.

An embodiment provides a technique that is capable of reducing or preventing occurring of a liquid splash on a substrate in a cleaning process with a mixed fluid.

A substrate processing apparatus according to an aspect of an embodiment includes a rotational holding part, a cleaning nozzle, a liquid supply nozzle, and a controller. The rotational holding part holds a substrate rotatably. The cleaning nozzle is provided movably at an upper side of the substrate that is heled by the rotational holding part and rotates, from a central part to a peripheral part of the substrate, and discharges a mixed fluid of a cleaning liquid and a gas onto the substrate. The liquid supply nozzle is provided movably at an upper side of the substrate, integrally with the cleaning nozzle, and discharges a liquid onto the substrate. The controller controls each part. The cleaning nozzle is capable of discharging each of the cleaning liquid and the gas independently. The controller executes a first process, a second process, a third process, and a fourth process. The first process discharges the liquid from the liquid supply nozzle to a central part of the substrate so as to form a liquid film of the liquid on the substrate. The second process discharges the cleaning liquid from the cleaning nozzle to a central part of the substrate on the substrate where a liquid film of the liquid has been formed. The third process discharges the gas at a first flow rate from the cleaning nozzle onto the substrate so as to discharge the mixed fluid to a central part of the substrate. The fourth process moves the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

According to an embodiment, it is possible to reduce or prevent occurring of a liquid splash on a substrate in a cleaning process with a mixed fluid.

### Appendix (1):

A substrate processing apparatus, including:
a rotational holding part that holds a substrate rotatably;
a cleaning nozzle that is provided movably at an upper side of the substrate that is heled by the rotational holding part and rotates, from a central part to a peripheral part of the substrate, and discharges a mixed fluid of a cleaning liquid and a gas onto the substrate;
a liquid supply nozzle that is provided movably at an upper side of the substrate, integrally with the cleaning nozzle, and discharges a liquid onto the substrate; and
a controller that controls each part, wherein
the cleaning nozzle is capable of discharging each of the cleaning liquid and the gas independently, and
the controller executes:
   a first process that discharges the liquid from the liquid supply nozzle to a central part of the substrate so as to form a liquid film of the liquid on the substrate;
   a second process that discharges the cleaning liquid from the cleaning nozzle to a central part of the substrate on the substrate where a liquid film of the liquid has been formed;
   a third process that discharges the gas at a first flow rate from the cleaning nozzle onto the substrate so as to discharge the mixed fluid to a central part of the substrate; and
   a fourth process that moves the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

### Appendix (2):

The substrate processing apparatus according to appendix (1), wherein
the controller further executes:
   a fifth process that moves the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
   a sixth process that discharges a rinse liquid from the liquid supply nozzle that has moved to an upper side of a central part of the substrate to the substrate.

### Appendix (3):

The substrate processing apparatus according to appendix (2), wherein
the controller further executes
   a seventh process that first stops discharge of the gas and then stops discharge of the cleaning liquid in the cleaning nozzle, after starting the sixth process.

### Appendix (4):

The substrate processing apparatus according to any one of appendices (1) to (3), wherein
the controller further executes:
   a fifth process that moves the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
   an eighth process that changes a flow rate of the gas that is discharged from the cleaning nozzle that has moved to an upper side of a central part of the substrate to a third flow rate that is less than the second flow rate.

### Appendix (5):

The substrate processing apparatus according to any one of appendices (1) to (3), further including
a back surface nozzle that discharges another liquid to a back surface of the substrate that is held by the rotational holding part, wherein
the controller further executes
   a ninth process that discharges the another liquid at a temperature that is higher than a room temperature from the back surface nozzle to a back surface of the substrate when executing the fourth process.

### Appendix (6):

A substrate processing method, including:
a first step that discharges a liquid from a liquid supply nozzle to a central part of a substrate that rotates so as to form a liquid film of the liquid on the substrate;
a second step that discharges a cleaning liquid from a cleaning nozzle to a central part of the substrate on the substrate where a liquid film of the liquid has been formed;
a third step that discharges a gas at a first flow rate from the cleaning nozzle onto the substrate so as to discharge a mixed fluid of the cleaning liquid and the gas to a central part of the substrate; and
a fourth step that moves the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

### Appendix (7):

The substrate processing method according to appendix (6), further including:
a fifth step that moves the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
a sixth step that discharges a rinse liquid from the liquid supply nozzle that has moved to an upper side of a central part of the substrate to the substrate.

### Appendix (8):

The substrate processing method according to appendix (7), further including
a seventh step that first stops discharge of the gas and then stops discharge of the cleaning liquid in the cleaning nozzle after starting the sixth step.

### Appendix (9):

The substrate processing method according to any one of appendices (6) to (8), further including:
a fifth step that moves the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
an eighth step that changes a flow rate of the gas that is discharged from the cleaning nozzle that has moved to an upper side of a central part of the substrate to a third flow rate that is less than the second flow rate.

### Appendix (10):

The substrate processing method according to any one of appendices (6) to (8), further including
a ninth step that discharges another liquid at a temperature that is higher than a room temperature from a back surface nozzle to a back surface of the substrate when executing the fourth step.

It should be considered that an embodiment(s) as disclosed herein is/are not limitative but is/are illustrative in all aspects. In fact, it is possible to implement an embodiment(s) as described above in a variety of modes. Furthermore, an embodiment(s) as described above may be omitted, substituted, or modified in a variety of modes, without departing from the appended claims and an essence thereof.

What is claimed is:

1. A substrate processing apparatus, comprising:
a rotational holding part that holds a substrate rotatably;
a cleaning nozzle that is provided movably at an upper side of the substrate that is heled by the rotational holding part and rotates, from a central part to a peripheral part of the substrate, and discharges a mixed fluid of a cleaning liquid and a gas onto the substrate;
a liquid supply nozzle that is provided movably at an upper side of the substrate, integrally with the cleaning nozzle, and discharges a liquid onto the substrate; and
a controller that controls at least the rotational holding part, the cleaning nozzle, and the liquid supply nozzle, wherein
the cleaning nozzle is capable of discharging each of the cleaning liquid and the gas independently, and
the controller is configured to execute, at least,
discharging the liquid from the liquid supply nozzle to a central part of the substrate to form a liquid film of the liquid on the substrate,
discharging the cleaning liquid from the cleaning nozzle to a central part of the substrate where a liquid film of the liquid has been formed,
discharging the gas at a first flow rate from the cleaning nozzle onto the substrate to discharge the mixed fluid to a central part of the substrate, and
moving the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

2. The substrate processing apparatus according to claim 1, wherein
the controller is further configured to execute:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
discharging a rinse liquid from the liquid supply nozzle that has moved to an upper side of a central part of the substrate to the substrate.

3. The substrate processing apparatus according to claim 2, wherein
the controller is further configured to execute
first stopping discharge of the gas and then stopping discharge of the cleaning liquid in the cleaning nozzle, after starting discharging the rinse liquid.

4. The substrate processing apparatus according to claim 1, wherein
the controller is further configured to execute:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

5. The substrate processing apparatus according to claim 1, further comprising
a back surface nozzle that discharges another liquid to a back surface of the substrate that is held by the rotational holding part, wherein
the controller is further configured to execute
discharging the another liquid at a temperature that is higher than a room temperature from the back surface nozzle to a back surface of the substrate when executing moving the cleaning nozzle and the liquid supply nozzle.

6. The substrate processing apparatus according to claim 2, wherein
the controller is further configured to execute:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

7. The substrate processing apparatus according to claim 2, further comprising
a back surface nozzle that discharges another liquid to a back surface of the substrate that is held by the rotational holding part, wherein
the controller is further configured to execute
discharging the another liquid at a temperature that is higher than a room temperature from the back surface nozzle to a back surface of the substrate when executing moving the cleaning nozzle and the liquid supply nozzle.

8. The substrate processing apparatus according to claim 3, wherein
the controller is further configured to execute:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

9. The substrate processing apparatus according to claim 3, further comprising
a back surface nozzle that discharges another liquid to a back surface of the substrate that is held by the rotational holding part, wherein
the controller is further configured to execute
discharging the another liquid at a temperature that is higher than a room temperature from the back surface nozzle to a back surface of the substrate when executing moving the cleaning nozzle and the liquid supply nozzle.

10. A substrate processing method, comprising:
discharging a liquid from a liquid supply nozzle to a central part of a substrate that rotates to form a liquid film of the liquid on the substrate;
discharging a cleaning liquid from a cleaning nozzle to a central part of the substrate where a liquid film of the liquid has been formed;
discharging a gas at a first flow rate from the cleaning nozzle onto the substrate to discharge a mixed fluid of the cleaning liquid and the gas to a central part of the substrate; and
moving the cleaning nozzle that discharges the mixed fluid and the liquid supply nozzle that discharges the liquid from an upper side of a central part to an upper side of a peripheral part of the substrate while changing a flow rate of the gas that is discharged from the cleaning nozzle to a second flow rate that is greater than the first flow rate.

11. The substrate processing method according to claim 10, further comprising:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
discharging a rinse liquid from the liquid supply nozzle that has moved to an upper side of a central part of the substrate to the substrate.

12. The substrate processing method according to claim 11, further comprising
first stopping discharge of the gas and then stopping discharge of the cleaning liquid in the cleaning nozzle after starting discharging the rinse liquid.

13. The substrate processing method according to claim 10, further comprising:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

14. The substrate processing method according to claim 10, further comprising
discharging another liquid at a temperature that is higher than a room temperature from a back surface nozzle to a back surface of the substrate when executing moving the cleaning nozzle and the liquid supply nozzle.

15. The substrate processing method according to claim 11, further comprising:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

16. The substrate processing method according to claim 11, further comprising
discharging another liquid at a temperature that is higher than a room temperature from a back surface nozzle to a back surface of the substrate when executing moving the cleaning nozzle and the liquid supply nozzle.

17. The substrate processing method according to claim 12, further comprising:
moving the cleaning nozzle and the liquid supply nozzle from an upper side of a peripheral part to an upper side of a central part of the substrate while discharging the mixed fluid from the cleaning nozzle and discharging the liquid from the liquid supply nozzle after the cleaning nozzle reaches an upper side of a peripheral part of the substrate; and
changing a flow rate of the gas that is discharged from the cleaning nozzle that has moved to an upper side of a central part of the substrate to a third flow rate that is less than the second flow rate.

18. The substrate processing method according to claim 12, further comprising
discharging another liquid at a temperature that is higher than a room temperature from a back surface nozzle to a back surface of the substrate when executing moving the cleaning nozzle and the liquid supply nozzle.
